(19) United States
(12) Patent Application Publication
(10) Pub. No.: US 2026/0162747 A1
(43) Pub. Date: Jun. 11, 2026

(54) TEST CIRCUIT AND SEMICONDUCTOR APPARATUS INCLUDING THE SAME

(71) Applicant: SK hynix Inc., Icheon-si Gyeonggi-do (KR)

(72) Inventor: Jae Yong KANG, Icheon-si Gyeonggi-do (KR)

(73) Assignee: SK hynix Inc., Icheon-si Gyeonggi-do (KR)

(21) Appl. No.: 19/071,154

(22) Filed: Mar. 5, 2025

(30) Foreign Application Priority Data
Dec. 11, 2024 (KR) 10-2024-0183877

(51) Int. Cl. G11C 29/40; G11C 29/12; G11C 29/14

(52) U.S. Cl. CPC G11C 29/40; G11C 29/1201; G11C 29/14

(57) ABSTRACT

A test circuit includes a data compression circuit and an output control circuit. The data compression circuit compresses read data transmitted through a plurality of first signal lines to generate a plurality of test result signals and outputs the plurality of test result signals through a plurality of second signal lines. The output control circuit selects one of the plurality of test result signals and the read data in accordance with die identification information and a test mode signal, and sequentially outputs the selected signal through a preassigned pad, among a plurality of pads.

### CROSS-REFERENCES TO RELATED APPLICATION

The present application claims priority under 35 U.S.C. § 119(a) to Korean application number 10-2024-0183877 filed on Dec. 11, 2024, in the Korean Intellectual Property Office, which application is incorporated herein by reference in its entirety.

### BACKGROUND

### 1. Technical Field

Various embodiments generally relate to a semiconductor circuit, and, more particularly, to a test circuit and a semiconductor apparatus including the same

### 2. Related Art

A stacked semiconductor apparatus includes a plurality of semiconductor dies in a package. The plurality of semiconductor dies are electrically connected through bonding wires. As such, when connecting the plurality of semiconductor dies through bonding wires, the number of pads is limited due to physical constraints.

A semiconductor apparatus is required to perform test operations, and for this purpose, the semiconductor apparatus includes test-related circuit configurations. Therefore, it is necessary to develop a technology that can efficiently output test results using a limited number of pads for wire-bonded stacked semiconductor apparatus.

### SUMMARY

In an embodiment, a test circuit may include a data compression circuit and an output control circuit. The data compression circuit may be configured to compress read data transmitted through first signal lines to generate a plurality of test result signals, and may be configured to output the plurality of test result signals through second signal lines. The output control circuit may be configured to select one of the plurality of test result signals and the read data in accordance with die identification information and a test mode signal, and may be configured to sequentially output the selected signal through a preassigned one of a plurality of pads.

In an embodiment, a semiconductor apparatus may include a plurality of unit memory regions, a plurality of normal global lines, a data compression circuit, and an output control circuit. The plurality of normal global lines may be coupled in common with the plurality of unit memory regions. The data compression circuit may be configured to compress read data transmitted through the plurality of normal global lines to generate a plurality of test result signals, and may be configured to output the plurality of test result signals through a plurality of test global lines. The output control circuit may be configured to select one of the plurality of test result signals and the read data in accordance with die identification information and a test mode signal, and may be configured to sequentially output the selected signal through a preassigned one of a plurality of pads.

In an embodiment, a semiconductor apparatus may include a plurality of semiconductor dies, each having a plurality of pads coupled to each other through bonding wires, and may be configured such that when a test read command is input, the plurality of semiconductor dies simultaneously output test results through some of the plurality of pads in different order.

### BRIEF DESCRIPTION OF THE DRAWINGS

FIG. 1 is a diagram illustrating a configuration of a stacked semiconductor apparatus according to an embodiment of the present disclosure.

FIG. 2 is a diagram illustrating a configuration of a semiconductor die according to an embodiment of the present disclosure.

FIG. 3 is a diagram illustrating a configuration of a memory core of FIG. 2.

FIG. 4 is a diagram illustrating a configuration of a test circuit according to an embodiment of the present disclosure.

FIG. 5 is a diagram illustrating a partial configuration of the test circuit of FIG. 4.

FIG. 6 is a diagram illustrating a configuration of a control unit of FIG. 5.

FIG. 7 is a diagram illustrating a test method according to an embodiment of the present disclosure.

FIG. 8 is a diagram illustrating a test result output method according to an embodiment of the present disclosure.

### DETAILED DESCRIPTION

Various embodiments not only enable efficient testing of semiconductor apparatus with wire bonding structures without adding pads, but also reduce test time by enabling test result output by parallel testing with only one read command.

Hereinafter, embodiments of the present disclosure will be described in more detail with reference to the accompanying drawings.

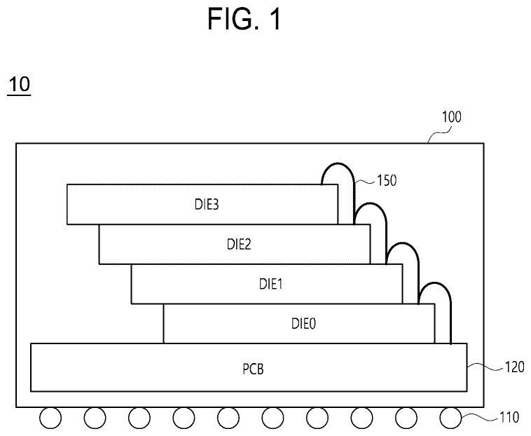

FIG. 1 is a diagram illustrating a configuration of a stacked semiconductor apparatus 10 according to an embodiment of the present disclosure.

Referring to FIG. 1, the stacked semiconductor apparatus 10 may include a package 100 and a plurality of external terminals 110. The package 100 may include a plurality of semiconductor dies DIE0-DIE3 mounted on a printed circuit board (PCB) 120.

The plurality of external terminals 110 may be implemented in the form of a plurality of package balls.

The plurality of semiconductor dies DIE0-DIE3 may be electrically connected to each other through bonding wire 150 and may be electrically connected to the plurality of external terminals 110 through the printed circuit board 120. Although not shown in FIG. 1, a plurality of pads included in each of the plurality of semiconductor dies DIE0-DIE3 may be electrically connected to each other through the bonding wire 150.

The plurality of semiconductor dies DIE0-DIE3 may each include volatile memory or non-volatile memory.

When a test read command is input to the stacked semiconductor apparatus 10, the plurality of semiconductor dies DIE0-DIE3 may simultaneously output test results through some of the plurality of pads in different order.

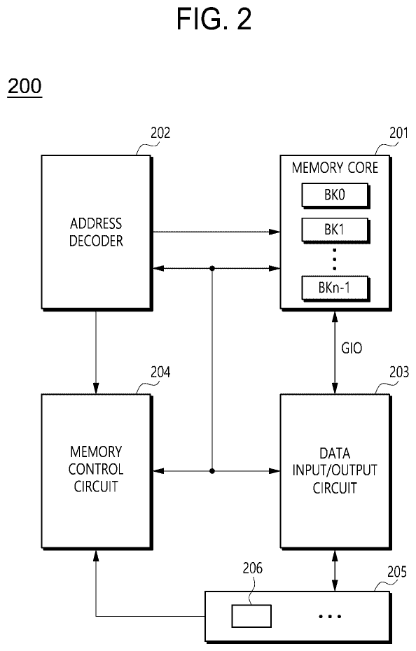

FIG. 2 is a diagram illustrating a configuration of a semiconductor die 200 according to an embodiment of the present disclosure. The semiconductor die 200 of FIG. 2 may be any one of the plurality of semiconductor dies DIE0-DIE3 of FIG. 1.

Referring to FIG. 2, the semiconductor die 200 may include a memory core 201, an address decoder 202, a data input/output circuit 203, a memory control circuit 204, and an input/output pad circuit 205.

The memory core 201 may include a plurality of memory cells, and the plurality of memory cells may include at least one of volatile memory and non-volatile memory. The volatile memory may include static RAM (SRAM), dynamic RAM (DRAM), and synchronous DRAM (SDRAM), and the non-volatile memory may include read only memory (ROM), programmable ROM (PROM), electrically erase and programmable ROM (EEPROM), electrically programmable ROM (EPROM), flash memory, phase change RAM (PRAM), magnetic RAM (MRAM), resistive RAM (RRAM), and ferroelectric RAM (FRAM). The memory core 201 may be divided into a plurality of unit memory regions, for example, a plurality of memory banks BK0-BKn-1.

The memory core 201 may compress read data output from each of the plurality of memory banks BK0-BKn-1 in a test operation, for example, a parallel test operation, to generate a plurality of test result signals, and may output the plurality of test result signals through a plurality of global lines GIO.

The address decoder 202 may be coupled with the memory control circuit 204 and the memory core 201. The address decoder 202 may decode an address signal provided by the memory control circuit 204 and may access the memory core 201 in response to the decoding result.

The data input/output circuit 203 may be coupled to the memory core 201 through the global lines GIO. The data input/output circuit 203 may exchange data with an external system or the memory core 201.

The data input/output circuit 203 may select one of the plurality of test result signals and read data transmitted through the plurality of global lines GIO in accordance with die identification information and a test mode signal and may sequentially output it through one of the pads preassigned, among a plurality of pads included in the input/output pad circuit 205.

The memory control circuit 204 may be coupled with the memory core 201, the address decoder 202, and the data input/output circuit 203. The memory control circuit 204 may provide addresses decoded through the address decoder 202 to the data input/output circuit 203. The memory control circuit 204 may control a test operation of the semiconductor die 200 and data input and output related operations. The data input and output related operations may include a normal read operation and a normal write operation.

The input/output pad circuit 205 may include a plurality of pads 206 for receiving commands, addresses, and clock signals, inputting and outputting data, and outputting test result signals.

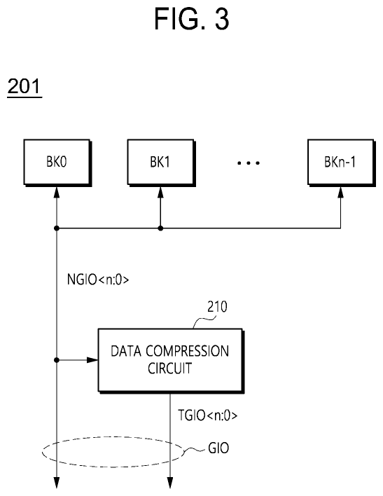

FIG. 3 is a diagram illustrating a configuration of the memory core 201 of FIG. 2.

Referring to FIG. 3, the memory core 201 may include a plurality of memory banks BK0-BKn-1 and a data compression circuit 210.

The plurality of memory banks BK0-BKn-1 may be coupled in common to first signal lines, i.e., a plurality of normal global lines NGIO<n:0>.

The data compression circuit 210 may compress read data transmitted through the plurality of normal global lines NGIO<n:0> to generate the plurality of test result signals and may output the plurality of test result signals through second signal lines, i.e., a plurality of test global lines TGIO<n:0>.

The data compression circuit 210 may compress the read data output from each of the plurality of memory banks BK0-BKn-1 to generate the plurality of test result signals in a parallel test operation and may output each signal bit of the plurality of test result signals through each of the plurality of test global lines TGIO<n:0>. More specifically, the data compression circuit 210 may compress read data output from a first memory bank BK0 to generate a test result signal and may output the generated test result signal to a test global line TGIO<0>. The data compression circuit 210 may compress read data output from a second memory bank BK1 to generate a test result signal and may output the generated test signal to a test global line TGIO<1>. In the manner described above, the data compression circuit 210 may compress read data output from a sixteenth memory bank BK15 to generate a test result signal and may output the generated test result signal to a test global line TGIO<15>.

The plurality of normal global lines NGIO<n:0> and the plurality of test global lines TGIO<n:0> may be included in the plurality of global lines GIO of FIG. 2.

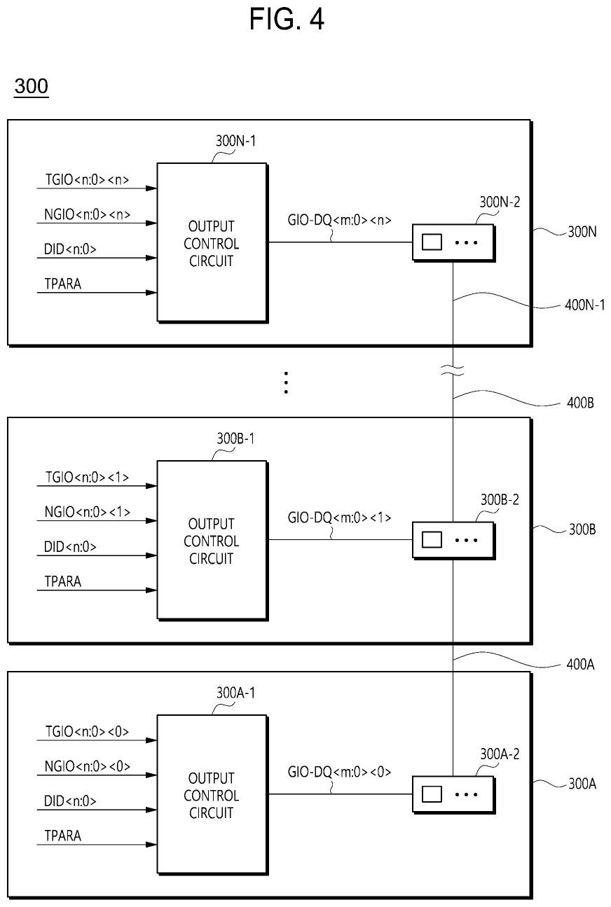

FIG. 4 is a diagram illustrating a configuration of a test circuit 300, according to an embodiment of the present disclosure.

Referring to FIG. 4, the test circuit 300 may include output control circuits 300A-1-300N-1 included in each of a plurality of semiconductor dies 300A-300N. The test circuit 300 may further include the data compression circuit 210, not shown in FIG. 4, but described with reference to FIG. 3.

The output control circuits 300A-1-300N-1 may be coupled with input/output pad circuits 300A-2-300N-2, respectively, through third signal lines GIO-DQ<m:0><n:0>.

The output control circuit 300A-1 of the semiconductor die 300A may be coupled with an input/output pad circuit 300A-2 through the third signal line GIO-DQ<m:0><0>, the output control circuit 300B-1 of the semiconductor die 300B may be coupled with an input/output pad circuit 300B-2 through the third signal line GIO-DQ<m:0><1>, and the output control circuit 300N-1 of the semiconductor die 300N may be coupled with an input/output pad circuit 300N-2 through the third signal line GIO-DQ<m:0><n>.

A plurality of pads included in each of the input/output pad circuits 300A-2-300N-2 may be coupled to each other in the same sequence by a plurality of bonding wires 400A-400N-1.

The plurality of pads included in the input/output pad circuit 300A-2 of the semiconductor die 300A may be coupled to each other in the same sequence as the plurality of pads included in the input/output pad circuit 300B-2 of the semiconductor die 300B by the plurality of bonding wires 400A. More specifically, a first pad, among the plurality of pads included in input/output pad circuit 300A-2, may be coupled to a first pad, among the plurality of pads included in input/output pad circuit 300B-2 of the semiconductor die 300B, by one of the plurality of bonding wires 400A, a second pad, among the plurality of pads included in input/output pad circuit 300A-2, may be coupled to a second pad, among the plurality of pads included in input/output pad circuit 300B-2 of the semiconductor die 300B, by another one of the plurality of bonding wires 400A. In the same way, an nth pad, among the plurality of pads included in the input/output pad circuit 300A-2, may be coupled to an nth pad, among the plurality of pads included in the input/output pad circuit 300B-2 of the semiconductor die 300B, by yet another one of the plurality of bonding wires 400A.

The plurality of pads included in the input/output pad circuit 300B-2 of the semiconductor die 300B may be coupled to each other in the same sequence as the plurality of pads included in the input/output pad circuit of a higher-level semiconductor die by the plurality of bonding wires 400B, and the plurality of pads included in the input/output pad circuit of a second higher-level semiconductor die may be coupled to each other in the same sequence as the plurality of pads 300N-2 included in the input/output pad circuit 300N-2 of the topmost semiconductor die 300N by the plurality of bonding wires 400N-1.

The output control circuits 300A-1-300N-1 may sequentially output one of read data transmitted through a plurality of normal global lines NGIO<n:0><n:0> and a plurality of test result signals transmitted through a plurality of test global lines TGIO<n:0><n:0> through a preassigned, a distinct pad, among the plurality of pads, according to die identification information DID<n:0> and a test mode signal TPARA.

The output control circuit 300A-1 of the lowermost semiconductor die 300A may select one of read data transmitted through the plurality of normal global lines NGIO<n:0><0> and the plurality of test result signals transmitted through the plurality of test global lines TGIO<n:0><0> according to the die identification information DID<n:0> and a test mode signal TPARA, and the selected signals may be sequentially output through one of the third signal lines GIO-DQ<m:0><0> coupled to a first pad of the input/output pad circuit 300A-2.

The output control circuit 300B-1 of the semiconductor die 300B may select one of read data transmitted through the plurality of normal global lines NGIO<n:0><1> and the plurality of test result signals transmitted through the plurality of test global lines TGIO<n:0><1> according to the die identification information DID<n:0> and the test mode signal TPARA, and the selected signals may be sequentially output through another third signal line GIO-DQ<m:0><1> coupled to a second pad of the input/output pad circuit 300B-2.

The output control circuit 300N-1 of the topmost semiconductor die 300N may select one of read data transmitted through the plurality of normal global lines NGIO<n:0><n> and the plurality of test result signals transmitted through the plurality of test global lines TGIO<n:0><n> according to the die identification information DID<n:0> and the test mode signal TPARA, and the selected signals may be sequentially output through another third signal line GIO-DQ<m:0><n> coupled with an nth pad of the input/output pad circuit 300N-2.

The signal output to the nth pad of the input/output pad circuit 300N-2 of the topmost semiconductor die 300N may be output to a device external to the semiconductor apparatus via the plurality of bonding wires 400A-400N-1 through an nth pad of the input/output pad circuit 300A-2 of the lowermost semiconductor die 300A. In the same manner, the signal output to the second pad of the input/output pad circuit 300B-2 of the semiconductor die 300B may be output to a device external to the semiconductor apparatus through a second pad of the input/output pad circuit 300A-2 of the lowermost semiconductor die 300A via the plurality of bonding wires 400A.

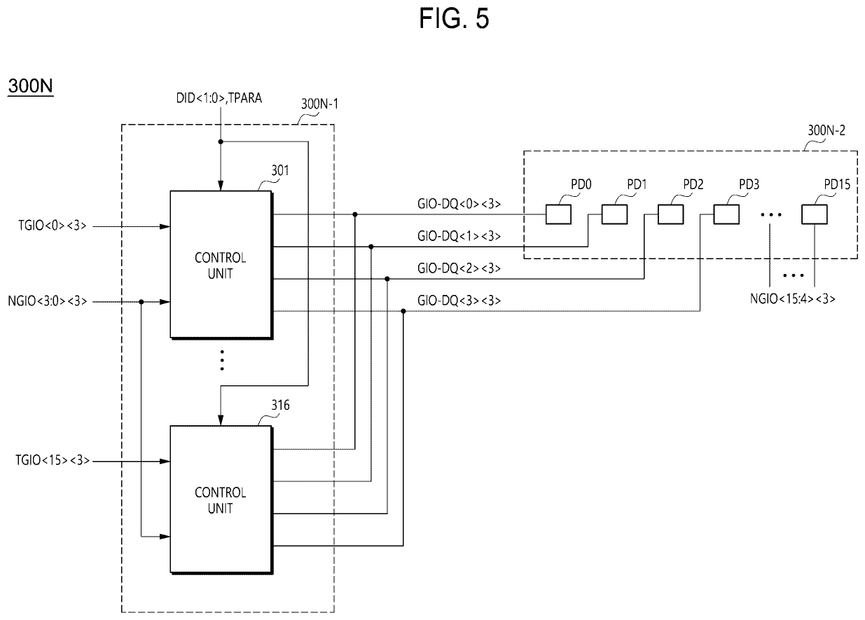

FIG. 5 is a diagram illustrating a partial configuration of the test circuit of FIG. 4. FIG. 5 illustrates an example in which a semiconductor apparatus according to an embodiment of the present disclosure is configured with four semiconductor dies, and accordingly configured with sixteen normal global lines NGIO<n:0>, sixteen test global lines TGIO<n:0>, and four third signal lines GIO-DQ<m:0>.

Referring to FIG. 5, the semiconductor die 300N may include the output control circuit 300N-1 and the input/output pad circuit 300N-2. The input/output pad circuit 300N-2 may include a plurality of pads PD0 to PD15 The output control circuit 300N-1 may include a plurality of control units 301-316.

The plurality of control units 301-316 may multiplex and output one of read data transmitted through a plurality of normal global lines NGIO<3:0><3> and a plurality of test result signals transmitted through a plurality of test global lines TGIO<15:0><3>, through partial pads PD0 to PD3 of the plurality of pads PD0 to PD15, according to die identification information DID<1:0> and the test mode signal TPARA. The rest of the normal global lines NGIO<15:4><3> are coupled to the rest of the pads PD4 to PD15.

The first control unit 301 may select one of read data transmitted through the normal global lines NGIO<3:0><3> and a test result signal transmitted through a test global line TGIO<0><3> according to the die identification information DID<1:0> and the test mode signal TPARA. The selected signal may then be output through one of a plurality of pads PD0 to PD15, such as PD3, which is coupled to one of the third signal lines GIO-DQ<3:0><3>, for example, GIO-DQ<3><3>.

Although not directly shown in FIG. 5, the second control unit 302 may select one of read data transmitted through the normal global lines NGIO<3:0><3> and a test result signal transmitted through a test global line TGIO<1><3> according to the die identification information DID<1:0> and the test mode signal TPARA and may output it through the pad PD3 coupled with the third signal line GIO-DQ<3><3>.

In the same way, the 16th control unit 316 may select one of read data transmitted through the normal global lines NGIO<3:0><3> and a test result signal transmitted through a test global line TGIO<15><3> according to the die identification information DID<1:0> and the test mode signal TPARA and may output it through the pad PD3 coupled with the third signal line GIO-DQ<3><3>.

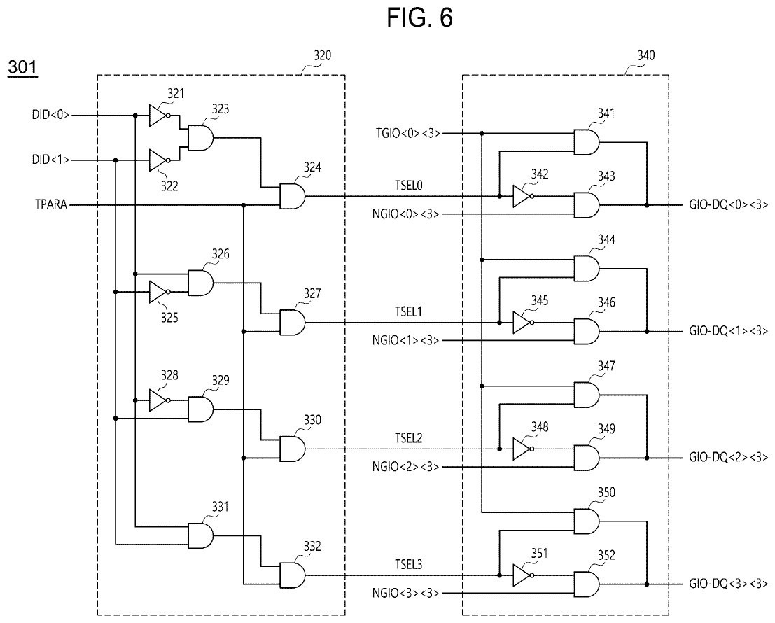

FIG. 6 is a diagram illustrating a configuration of the control unit 301 of FIG. 5.

Referring to FIG. 6, the control unit 301 may include a decoding circuit 320 and a multiplexing circuit 340.

The decoding circuit 320 may generate a plurality of selection signals TSEL<3:0> based on the die identification information DID<1:0> and the test mode signal TPARA.

The test mode signal TPARA may be activated when the semiconductor apparatus enters a test mode, such as a parallel test mode. The test mode signal TPARA may be deactivated in a normal mode of the semiconductor apparatus. The activation/deactivation of a signal may be distinguished by a logic level, and hereinafter, it is assumed that the signal is activated at a high level and deactivated at a low level.

The die identification information DID<n:0> may be information for identifying each of a plurality of semiconductor dies and may have a different value for each semiconductor die. The number of bits in the die identification information DID<n:0> may change depending on the number of semiconductor dies. The die identification information DID<n:0> may be adjusted to have a different value for each stacking position within the semiconductor apparatus or may be adjusted to have a different value for each stacking position outside the semiconductor apparatus. The die identification information DID<n:0> for each of the semiconductor dies may have the same initial value (e.g., ‘00’) prior to stacking and may increase by an increment of ‘1’ for each stacking position, such that the semiconductor dies have different die identification information DID<n:0>. For example, assuming four semiconductor dies are stacked, the semiconductor dies may store the die identification information DID<n:0> as ‘00’, ‘01’, ‘10’, and ‘11’ from the lowermost to the topmost positions, respectively.

The decoding circuit 320 may include a plurality of logic gates 321-332. The first logic gate 321 may invert the die identification information DID<0> and output the result. The second logic gate 322 may invert the die identification information DID<1> and output the result. The third logic gate 323 may output a result from performing an AND operation on an output of the first logic gate 321 and an output of the second logic gate 322. The fourth logic gate 324 may output a result from performing an AND operation on an output of the third logic gate 323 and the test mode signal TPARA as the first selection signal TSEL0. The fifth logic gate 325 may invert the die identification information DID<1> and output the result. The sixth logic gate 326 may output a result from performing an AND operation on an output of the fifth logic gate 325 and the die identification information DID<0>. The seventh logic gate 327 may output a result from performing an AND operation on an output of the sixth logic gate 326 and the test mode signal TPARA as the second selection signal TSEL1. The eighth logic gate 328 may invert the die identification information DID<0> and output the result. The ninth logic gate 329 may output a result from performing an AND operation on an output of the eighth logic gate 328 and the die identification information DID<1>. The tenth logic gate 330 may output a result from performing an AND operation on an output of the ninth logic gate 329 and the test mode signal TPARA as the third selection signal TSEL2. The eleventh logic gate 331 may output a result from performing an AND operation on the die identification information DID<0> and the die identification information DID<1>. The twelfth logic gate 332 may output a result from performing an AND operation on an output of the eleventh logic gate 331 and the test mode signal TPARA as the fourth selection signal TSEL3.

The decoding circuit 320 may deactivate all of the plurality of selection signals TSEL<3:0>, independent of the die identification information DID<1:0>, when the test mode signal TPARA is deactivated. The decoding circuit 320 may activate one of the plurality of selection signals TSEL<3:0> based on the die identification information DID<1:0> when the test mode signal TPARA is activated. The decoding circuit 320 may activate only the first selection signal TSEL0 if a value of the die identification information DID<1:0> is ‘00’, activate only the second selection signal TSEL1 if a value of the die identification information DID<1:0> is ‘01’, activate only the third selection signal TSEL2 if a value of the die identification information DID<1:0> is ‘10’, and activate only the fourth selection signal TSEL3 if a value of the die identification information DID<1:0> is ‘11’.

The multiplexing circuit 340 may select and output one of read data transmitted through the normal global lines NGIO<3:0><3> and the test result signal transmitted through the test global line TGIO<0><3> according to the plurality of selection signals TSEL<3:0>.

The multiplexing circuit 340 may include a plurality of logic gates 341-352. The first logic gate 341 may output a result from performing an AND operation on the test result signal transmitted through the test global line TGIO<0><3> and the first selection signal TSEL0 to the third signal line GIO-DQ<0><3>. The second logic gate 342 may invert the first selection signal TSEL0 and output the result. The third logic gate 343 may output a result from performing an AND operation on an output of the second logic gate 342 and read data transmitted through the normal global line NGIO<0><3> to the third signal line GIO-DQ<0><3>. The fourth logic gate 344 may output a result from performing an AND operation on the test result signal transmitted through the test global line TGIO<0><3> and the second selection signal TSEL1 to the third signal line GIO-DQ<1><3>. The fifth logic gate 345 may invert the second selection signal TSEL1 and output the result. The sixth logic gate 346 may output a result from performing an AND operation on an output of the fifth logic gate 345 and read data transmitted through the normal global line NGIO<1><3> to the third signal line GIO-DQ<1><3>. The seventh logic gate 347 may output a result from performing an AND operation on the test result signal transmitted through the test global line TGIO<0><3> and the third selection signal TSEL2 to the third signal line GIO-DQ<2><3>. The eighth logic gate 348 may invert the third selection signal TSEL2 and output the result. The ninth logic gate 349 may output a result from performing an AND operation on an output of the eighth logic gate 348 and read data transmitted through the normal global line NGIO<2><3> to the third signal line GIO-DQ<2><3>. The tenth logic gate 350 may output a result from performing an AND operation on the test result signal transmitted through the test global line TGIO<0><3> and the fourth selection signal TSEL3 to the third signal line GIO-DQ<3><3>. The eleventh logic gate 351 may invert the fourth selection signal TSEL3 and output the result. The twelfth logic gate 352 may output a result from performing an AND operation on an output of the eleventh logic gate 351 and read data transmitted through the normal global line NGIO<3><3> to the third signal line GIO-DQ<3><3>.

The multiplexing circuit 340 may output the read data transmitted through the normal global lines NGIO<3:0><3> to all of the third signal lines GIO-DQ<3:0><3> upon a deactivation of the plurality of selection signals TSEL<3:0>. When any one of the plurality of selection signals TSEL<3:0> is activated, the multiplexing circuit 340 may output the test result signal transmitted through the test global lines TGIO<0><3> to a signal line corresponding to the activated selection signal, among the third signal lines GIO-DQ<3:0><3>.

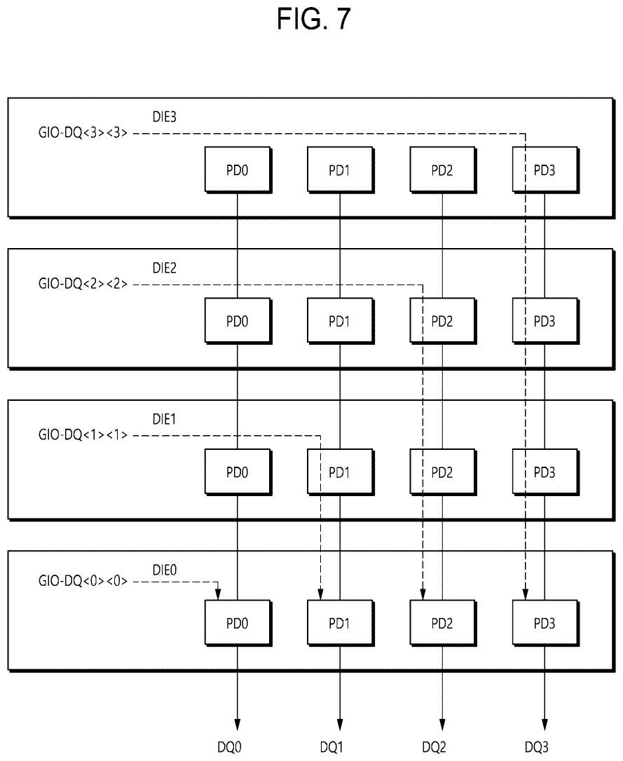

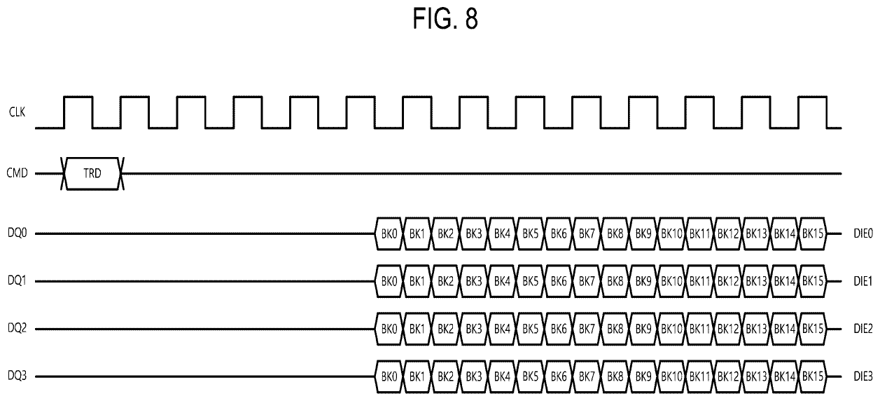

FIG. 7 is a diagram illustrating a test method according to an embodiment of the present disclosure, and FIG. 8 is a diagram illustrating a test result output method according to an embodiment of the present disclosure.

Hereinafter, a parallel test method according to an embodiment of the present disclosure will be described with reference to FIGS. 1 to 8. It is assumed that the semiconductor apparatus is in the form of four semiconductor dies stacked together, and that each semiconductor die has 16 memory banks. It is also assumed that the die identification information DID<1:0> of the four semiconductor dies have values of ‘00’, ‘01’, ‘10’, and ‘11’ from the first semiconductor die DIE0, which is the lowermost semiconductor die, to the fourth semiconductor die DIE3, which is the topmost semiconductor die, respectively.

The test mode signal TPARA may be activated as the test mode is entered.

In each of the semiconductor dies, the 16 memory banks BK0-BK15 may sequentially output read data to the plurality of normal global lines NGIO<15:0> in accordance with a test read command TRD, and the data compression circuit 210 may sequentially output 1-bit unit test result signals generated by compressing the data output from the 16 memory banks BK0-BK15 to the plurality of test global lines TGIO<15:0>.

For example, in each of the semiconductor dies, if the 16 memory banks BK0-BK15 sequentially output read data according to their sequence, 1-bit test result signal of each memory bank may be sequentially written to a test global line in the same sequence as the sequence of the memory bank. More specifically, a test result signal generated according to read data output from the first memory bank BK0 may be transmitted to the test global line TGIO<0>, a test result signal generated according to read data output from the second memory bank BK1 after a first time may be transmitted to the test global line TGIO<1>, and in the same manner, test result signals corresponding to the remaining memory banks BK2-BK15 may be sequentially output through the test global lines TGIO<15:2>.

The first semiconductor die DIE0 may have a die identification information DID<1:0> of ‘00’so the first selection signal TSEL0 is activated as the test mode signal TPARA is activated. The second semiconductor die DIE1 may have a die identification information DID<1:0> of ‘01’ so the second selection signal TSEL1 is activated as the test mode signal TPARA is activated. The third semiconductor die DIE2 may have a die identification information DID<1:0> of ‘10’ so the third selection signal TSEL2 is activated as the test mode signal TPARA is activated. The fourth semiconductor die DIE4 may have a die identification information DID<1:0> of ‘11’ so the fourth selection signal TSEL3 is activated as the test mode signal TPARA is activated.

Referring to FIG. 7, the first semiconductor die DIE0 may output a plurality of test result signals transmitted sequentially through a plurality of test global lines TGIO<15:0><0> as the first selection signal TSEL0 is activated, to a device external to the semiconductor apparatus, such as an external package pad DQ0, through a first pad PD0 coupled to a third signal line GIO-DQ<0><0>.

The second semiconductor die DIE1 may output a plurality of test result signals sequentially transmitted through a plurality of test global lines TGIO<15:0><1> as the second selection signal TSEL1 is activated, to a device external to the semiconductor apparatus, such as an external package pad DQ1, through a second pad PD1 coupled to a third signal line GIO-DQ<1><1> and a second pad PD1 of the first semiconductor die DIE0.

The third semiconductor die DIE2 may output a plurality of test result signals sequentially transmitted through a plurality of test global lines TGIO<15:0><2> as the third selection signal TSEL2 is activated, to a device external to the semiconductor apparatus, such as an external package pad DQ2, through a third pad PD2 coupled to a third signal line GIO-DQ<2><2>, a third pad PD2 of the second semiconductor die DIE1, and a third pad PD2 of the first semiconductor die DIE0.

The fourth semiconductor die DIE3 may output a plurality of test result signals sequentially transmitted through a plurality of test global lines TGIO<15:0><3> as the fourth selection signal TSEL3 is activated, to a device external to the semiconductor apparatus, such as an external package pad DQ3, through a fourth pad PD3 coupled to a third signal line GIO-DQ<3><3>, a fourth pad PD3 of the third semiconductor die DIE2, a fourth pad PD3 of the second semiconductor die DIE1, and a fourth pad PD3 of the first semiconductor die DIE0.

As shown in FIG. 8, an embodiment of the present disclosure enters a test mode, and when a test read command TRD is input, a test result output is made by performing a parallel test after a predetermined time based on a clock signal CLK. The first to fourth semiconductor dies DIE0-DIE3 can simultaneously output 1-bit test result signals according to each of the 16 memory banks BK0-BK15 through one pad each for 16 burst length.

As mentioned above, the pads DQ0-DQ3 to which the test result output is made are not separately allocated or are not added pads specifically for the test. The pads are shared even during normal read/write operation. Thus, the semiconductor apparatus according to an embodiment of the present disclosure not only enables efficient testing without the addition of pads, but also reduces test time because parallel test result output for all memory regions is possible with only one read command.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the provided descriptions. All changes within the meaning and range of equivalency of the claims are included within their scope.

What is claimed is:

1. A test circuit, comprising:
a data compression circuit configured to compress read data transmitted through a plurality of first signal lines to generate a plurality of test result signals and configured to output the plurality of test result signals through a plurality of second signal lines; and
an output control circuit configured to select one of the plurality of test result signals and the read data in accordance with die identification information and a test mode signal and configured to sequentially output the selected signal through a preassigned pad, among a plurality of pads.

2. The test circuit of claim 1, wherein the output control circuit includes a plurality of control units configured to multiplex some bits of the read data and one of the plurality of test result signals according to the die identification information and the test mode signal.

3. The test circuit of claim 2, wherein each of the plurality of control units comprises:
a decoding circuit configured to generate a plurality of selection signals according to the die identification information and the test mode signal; and
a multiplexing circuit configured to select and output one of each of the some bits of the read data and one of the plurality of test result signals according to the plurality of selection signals.

4. A semiconductor apparatus, comprising:
a plurality of unit memory regions;
a plurality of normal global lines coupled in common with the plurality of unit memory regions;
a data compression circuit configured to compress read data transmitted through the plurality of normal global lines to generate a plurality of test result signals and configured to output the plurality of test result signals through a plurality of test global lines; and
an output control circuit configured to select one of the plurality of test result signals and the read data in accordance with die identification information and a test mode signal and configured to sequentially output the selected signal through a preassigned pad, among a plurality of pads.

5. The semiconductor apparatus of claim 4, wherein the data compression circuit is configured to output a signal compressing read data output from one of the plurality of unit memory regions as one of the plurality of test result signals.

6. The semiconductor apparatus of claim 4, wherein the output control circuit includes a plurality of control units configured to multiplex some bits of the read data and one of the plurality of test result signals according to the die identification information and the test mode signal.

7. The semiconductor apparatus of claim 6, wherein each of the plurality of control units comprises:
a decoding circuit configured to generate a plurality of selection signals according to the die identification information and the test mode signal; and
a multiplexing circuit configured to select and output one of each of the some bits of the read data and one of the plurality of test result signals according to the plurality of selection signals.

8. A semiconductor apparatus, comprising a plurality of semiconductor dies, each having a plurality of pads coupled to each other through bonding wires, and configured such that when a test read command is input, the plurality of semiconductor dies simultaneously output test results through some of the plurality of pads in different order.

9. The semiconductor apparatus of claim 8, wherein each of the plurality of semiconductor dies includes an output control circuit configured to select signals transmitted through one of a plurality of test global lines and a plurality of normal global lines in accordance with die identification information and a test mode signal and configured to output the selected signals through one of the some pads.

10. The semiconductor apparatus of claim 8, each of the plurality of semiconductor dies includes a plurality of control units configured to multiplex and output a first set of signals transmitted through some of a plurality of normal global lines and a second signal transmitted through one of a plurality of test global lines, according to die identification information and a test mode signal.

11. The semiconductor apparatus of claim 10, wherein each of the plurality of control units comprises:
a decoding circuit configured to generate a plurality of selection signals based on the die identification information and the test mode signal; and
a multiplexing circuit configured to select and output one of each of the first set of signals and the second signal according to the plurality of selection signals.

12. The semiconductor apparatus of claim 8, wherein each of the plurality of semiconductor dies includes:
a plurality of normal global lines coupled in common with a plurality of unit memory regions;
a data compression circuit configured to output a plurality of test result signals through a plurality of test global lines generated by compressing read data transmitted through the plurality of normal global lines; and
an output control circuit, and
wherein, when the test read command is input, an output control circuit of a first semiconductor die, which is the lowermost among the plurality of semiconductor dies, is configured to output the plurality of test result signals through a first pad of the plurality of pads, and an output control circuit of a second semiconductor die stacked on the first semiconductor die is configured to output the plurality of test result signals through a second pad of the plurality of pads simultaneously.

13. The semiconductor apparatus of claim 12, wherein, when a normal read command is input, an output control circuit of one of the plurality of semiconductor dies is configured to output read data transmitted through the plurality of normal global lines to the plurality of pads.

14. The semiconductor apparatus of claim 12, wherein the data compression circuit is configured to output a signal compressing read data output from one of the plurality of unit memory regions as one of the plurality of test result signals.

15. The semiconductor apparatus of claim 12, wherein the output control circuit includes a plurality of control units configured to multiplex some bits of the read data and one of the plurality of test result signals according to die identification information and a test mode signal.

16. The semiconductor apparatus of claim 15, wherein each of the plurality of control units comprises:
a decoding circuit configured to generate a plurality of selection signals according to the die identification information and the test mode signal; and
a multiplexing circuit configured to select and output one of each of the some bits of the read data and one of the plurality of test result signals according to the plurality of selection signals.
